(19) United States
(12) Patent Application Publication
(10) Pub. No.: US 2020/0295206 A1
(43) Pub. Date: Sep. 17, 2020

(54) CONDUCTIVE PASTE AND SOLAR CELL USING THE SAME

(71) Applicant: PANCOLOUR INK CO., LTD., Taoyuan City (TW)

(72) Inventors: YING-HUA HUANG, TAOYUAN CITY (TW); HUNG-ING CHANG, TAOYUAN CITY (TW); YU-CHING PAI, TAOYUAN CITY (TW)

(21) Appl. No.: 16/352,983

(22) Filed: Mar. 14, 2019

(51) Int. Cl. H01L 31/0224; H01L 31/068; H01L 31/18; H01B 1/22

(52) U.S. Cl. CPC H01L 31/022441; H01B 1/22; H01L 31/1868; H01L 31/068

(57) ABSTRACT

A conductive paste composed of an aluminum powder, an organic carrier consisting of an organic solvent and resin or cellulose, a glass powder, and a lead oxide. A total content of the glass powder and the lead oxide is from about 1.0 to 6.0 wt % of the conductive paste; and a content of the lead oxide is from about 0.5 to 3.0 wt % of the conductive paste. The conductive paste contains specific percentages of glass powder and lead oxide and can be used in manufacturing solar cells, and the solar cells so manufactured can have increased photovoltaic conversion efficiency without the need of using any expensive laser drilling apparatus, large plant space and any precision-alignment printing machine. With these advantages, the conductive paste is able to promote photovoltaic industry upgrading.

### FIELD OF THE INVENTION

The present invention relates to a conductive paste and a solar cell using the conductive paste.

### BACKGROUND OF THE INVENTION

In the existing energy source field, it has been proposed to manufacture flat crystalline silicon using monocrystalline silicon or polycrystalline silicon for use as a component in a semiconductor device, such as a substrate of a crystalline silicon solar cell. And, to enable electrical contact of the substrate with an outer side of the semiconductor device, electrodes are formed on the surface of the silicon substrate using an electrically conductive paste. Among the semiconductor devices that have electrodes formed in the above manner, crystalline silicon solar cells have been particularly widely manufactured in recent years. These crystalline silicon solar cells include an impurity diffusion layer, an antireflection layer (also referred to as a front side passivation layer) and light-incident-side electrodes provided on a front side of the silicon substrate, as well as back side electrodes provided on a back side of the silicon substrate. When light is incident on the crystalline silicon substrate, electricity generated by the crystalline silicon solar cell is transmitted to an external environment via the electrodes.

When the solar cells are developed from the conventional crystalline silicon solar cells to passivated emitter rear contact (PERC) solar cells or bifacial PERC solar cells, it is necessary to use laser to ablate the back side passivation layer and form laser contact openings (LCO) in the shape of lines, dash-lines or dots. Typically, the PERC solar cells are formed by full-area printing, while the bifacial PERC solar cells are formed by fine-line printing. The fine-line printing requires accurately alignment, so that the solar cell after a sintering process can have good contacts and less aluminum layer covering area to obtain better electrical characteristics.

In the process of laser abration, a laser drilling apparatus is required. Further, to enable accurate alignment, it is necessary to use a printing machine having a precision alignment system.

### SUMMARY OF THE INVENTION

However, the laser drilling apparatus and the printing machine capable of precision alignment are expensive and require very large plant space to mount them, which inevitably increases the cost burden of the solar cell manufacturers. It is found by the inventor of the present patent application that, when a conductive paste capable of firing through the passivation layer (hereinafter briefly referred to as the conductive paste) is used along with a fine-line screen-printing plate to be printed on the surface of the back side passivation layer, the compositions in the conductive paste react with the back side passivation layer to destroy (or fire through) the latter when the conductive paste is sintered by passing it through a high-temperature furnace. Thereafter, three-valence elements contained in the conductive paste, such as boron, aluminum and gallium, together with the silicon substrate form a p+doped channel and an electrically conductive layer.

When using the conductive paste capable of firing through the passivation layer to manufacture solar cells, the traditional solar cell manufacturers can easily transform into the field of high-efficiency solar cells without the need of investing more money in new apparatuses and large plant space. A more detailed description about this follows below.

A PERC solar cell generally includes a front side passivation layer, which is usually an antireflection layer of silicon nitride (Si₃N₄) having a thickness from about 40 to 50 nm provided on a front light-receiving surface of the solar cell; a P-N junction formed at about 1 to 2 μm below the front light-receiving surface; and a back side passivation layer provided on a back surface opposite to the light-receiving surface for decreasing carrier recombination. Back side passivation layers manufactured in different processes might be different in thickness and chemical properties. For example, the back side passivation layer can be formed through the Atomic Layer Deposition (ALD) process or the Plasma Enhanced Chemical Vapor Deposition (PECVD) process, in which a layer of aluminum oxide (Al₂O₃) is first deposited and a layer of silicon nitride (SiNₓ or Si₃N₄) is then deposited. The back side passivation layer can be otherwise formed by depositing silicon oxynitride (SiNOₓ) in a thermal oxidation furnace.

Generally, most discussions of conventional conductive paste with fire-through capability are focused on the fire-through of the front side passivation layer, such as a Si₃N₄ antireflection layer of the p-type solar cell, without firing through the P-N junction in order to avoid overburning.

According to an embodiment of the present invention, the conductive paste fires through the back side passivation layer. More specifically, when the conductive paste according to an embodiment of the present invention is passed through a high-temperature furnace in a sintering process, the compositions in the paste react with the back side passivation layer to destroy or fire through the latter to thereby expose the silicon substrate. This condition increases the eutectic reaction between silicon and aluminum (or an aluminum alloy powder as described later in other embodiments) to provide the substrate with good local electrical contact. The forming of more fire-through areas indicates more contact of aluminum or aluminum alloy powder with silicon substrate is available. By providing the substrate with good electrical contact in the above manner, the solar cell can have upgraded photovoltaic conversion efficiency.

Further, during the 50- to 60-second sintering process, the conductive paste must be able to form a proper back surface field (BSF) at the same time of firing through the passivation layer. Therefore, according to an embodiment of the present invention, a proper quantity of aluminum-silicon alloy powder is added to the conductive paste, so as to reduce the outward diffusion speed of silicon from the substrate at the high-temperature sintering areas and accordingly, increase the silicon concentration in the molten aluminum at the fire-through points. The adding of aluminum-silicon alloy powder to the conductive paste also increases the chance of forming a relatively thick BSF layer to increase the open circuit voltage (V_{oc}) and the photovoltaic conversion efficiency of the solar cell.

In the existing solar cell manufacturing process, the back side passivation layer of the solar cell is partially removed using laser to form dot-shaped, line-shaped, or dash-line-shaped contact openings on the passivation layer. Therefore, when printing the aluminum paste on the silicon substrate, it is necessary to stack the solar cell substrates at the location for forming the above-mentioned laser contact openings.

Meanwhile, for the bifacial PERC solar cell formed by fine-line printing to also provide good back side efficiency, it is necessary to limit the linewidth of the printed fine-line. For this purpose, the laser contact openings and the fine-line printing positions must be properly aligned with one another to obtain better electrical characteristics and solar cell efficiency. To do this, locating points must be provided on the back side of the solar cell in advance and then, a printing machine with a charge-coupled device (CCD) alignment system is used to print the conductive paste on the back side of the solar cell according to the locating points. However, the alignment tends to fail in the event the reflectance is different at different locating points.

From the above analyses, it can be found the use of the conductive paste according to the present invention enables fire-through of the back side passivation layer of the solar cell while it is no longer necessary to remove the back side passivation layer using laser or to provide locating holes on the back side passivation layer. In other words, when using the conductive paste of the present invention in manufacturing solar cells, only an ordinary single printing is sufficient without the need of using any specific alignment mechanism. That is, no precision-alignment printing machine is required in manufacturing the solar cell when using the conductive paste of the present invention.

It is also found the use of the conductive paste of the present invention not only saves the troubles of using a precision-alignment printing machine, buying the expensive laser drilling apparatus and preparing a large plant space, but also increases the photovoltaic conversion efficiency of the solar cell to promote photovoltaic industry upgrading.

To achieve the above and other objects, the present invention provides a conductive paste that is composed of an aluminum powder; an organic carrier consisting of an organic solvent and resin or cellulose; a glass powder; and a lead oxide. A total content of the glass powder and the lead oxide is from about 1.0 to 6.0 wt % of the conductive paste; and a content of the lead oxide is from about 0.5 to 3.0 wt % of the conductive paste.

According to an embodiment of the present invention, the total content of the glass powder and the lead oxide is from about 2.0 to 5.0 wt % of the conductive paste, and the content of the lead oxide is from about 1.0 to 2.0 wt % of the conductive paste.

According to an embodiment of the present invention, the glass powder is a glass powder containing a lead-containing oxide.

According to an embodiment of the present invention, the lead oxide is lead monoxide (PbO).

According to an embodiment of the present invention, the organic solvent is selected from the group consisting of terpineol, 2,2,4-trimethyl-1,3-pentanediol monoisobutyrate (texanol), diethylene glycol monobutyl ether, and any combination thereof; and a content of the organic solvent is from about 10 to 25 wt % of the conductive paste.

According to an embodiment of the present invention, the organic carrier further includes additives selected from the group consisting of antioxidants, corrosion inhibitors, antifoaming agents, thickeners, adhesion promoters, coupling agents, static electricity imparting agents, polymerization inhibitors, thixotropic agents, ant-setting agents, and any combination thereof; and a total content of the additives is from about 0.2 to 2.0 wt % of the conductive paste.

According to an embodiment of the present invention, the conductive paste further includes an aluminum-silicon alloy powder. A content of the aluminum-silicon alloy powder is from about 5 to 20 wt % of the conductive paste; and a total content of the aluminum powder and the aluminum-silicon alloy powder is from about 60 to 85 wt % of the conductive paste.

According to an embodiment of the present invention, the content of the aluminum-silicon alloy powder is from about 10 to 15 wt % of the conductive paste.

According to an embodiment of the present invention, the aluminum-silicon alloy powder contains from about 12 to 20 wt % silicon and has a median particle diameter (D50) from about 1 to 7 μm.

The present invention also provides a solar cell with a back side passivation layer and being characterized in comprising the conductive paste provided according to the present invention.

The use of the conductive paste according to the present invention in manufacturing solar cells can provide the advantages of enabling increased photovoltaic conversion efficiency, saving the trouble of using expensive laser drilling apparatus and large plant space, and saving the trouble of using a precision-alignment printing machine.

### DETAILED DESCRIPTION OF THE PREFERRED EMBODIMENTS

The objects, features and functions of the present invention can be best understood by referring to the following detailed description of some preferred embodiments of the present invention.

It is noted that, where there is not particularly described, “%” used herein indicates “weight %”.

The present invention provides a conductive paste composed of an aluminum powder, an organic carrier, a glass powder, and a lead oxide. The organic carrier is composed of an organic solvent and resin or cellulose. The conductive paste according to the present invention contains from about 1.0 to 6.0 wt % glass powder and lead oxide. More specifically, the conductive paste of the present invention contains from about 0.5 to 3.0 wt % lead oxide. Further, the lead oxide is selected from the group consisting of lead monoxide (PbO), lead dioxide (PbO₂), red lead (Pb₃O₄), and any other suitable lead oxide.

In a preferred embodiment of the present invention, the conductive paste contains from about 2.0 to 5.0 wt % glass powder and lead oxide; and more specifically, the conductive paste contains from about 1.0 to 2.0 wt % lead oxide.

When the glass powder and the lead oxide in specific percentages are used at the same time, the glass powder having a melting point (e.g., about 300° C.) lower than that of the lead oxide (e.g., about 500° C.) is molten first in a process of sintering at about 720° C. to 820° C. to form a path along which a back side passivation layer of a solar cell substrate will be fired through later. This path is therefore referred to as the fire-through path herein. Then, with the increasing sintering temperature, the lead oxide having a higher melting point is also molten to fire through (i.e. destroy) the back side passivation layer along the fire-through path.

It is found by the inventor that the fire-through path can be more effectively formed when the glass powder containing a lead oxide, such as lead monoxide (PbO), is used in the conductive paste.

Moreover, it is preferable to use a lead monoxide (PbO) having purity higher than 99.0% and a median particle diameter (D50) from about 1.5 to 3.5 μm.

The aluminum contained in the conductive paste and the silicon in the silicon-based solar cell intersperse themselves at the molten interface of the passivation layer before the latter is fired through. With the rising sintering temperature, the resulting molten aluminum reacts with the silicon substrate of the solar cell more quickly, bringing the aluminum to diffuse into the silicon substrate. As a result, an aluminum-silicon (Al—Si) alloy layer is formed between the aluminum electrode layer (i.e. the conductive paste) and the silicon substrate. Meanwhile, a p+ layer (also referred to as the back surface field (BSF) layer) is also formed to serve as an impurity layer for aluminum-based atomic diffusion. The existence of the p+ layer provides the BSF effects of preventing electron recombination and enhancing the collection efficiency of generated charge carriers. By forming the BSF layer in the above manner, it is able to enhance the electrical characteristics of the solar cell and accordingly, simplify the manufacturing process of the PERC silicon solar cell.

It is also found by the inventor that the passivation layer could not be effectively fired through when only the lead oxide is used and no glass powder is added.

Therefore, a method of preparing the conductive paste according to the preferred embodiment of the present invention includes at two steps, namely, a first step S1 and a second step S2.

In the first step S1, an organic solvent is mixed with a resin or cellulose to form an evenly mixed organic carrier. It should be noted that, in the first step S1, other additives can be added according to actual requirements to form the organic carrier.

In the second step S2, a mixer or a three-roller mill (e.g., Model No. Exakt 80E supplied by Exakt Technologies) is used to mix the aluminum powder, the glass powder and the lead oxide with the organic carrier and the mixture is milled and dispersed to form the conductive paste. It should be noted that, in the second step S2, other additives and additional resins or celluloses can be added according to actual requirements.

Further, in the first step S1, the organic carrier has a viscosity from about 1 to 15 Kcps, preferably from about 10 to 15 Kcps. The conductive paste can have the best viscosity by controlling the viscosity of the organic carrier.

Further, in the first step S1, the organic solvent can be a glycol ether solvent or other solvents. Some examples of organic solvents include terpineol, 2,2,4-trimethyl-1,3-pentanediol monoisobutyrate (texanol), and diethylene glycol monobutyl ether. While it is not particularly specified, the content of the organic solvent in the conductive paste is preferably from about 10 to 25 wt % of the total weight of the conductive paste.

Also, in the first step S1, the content of the cellulose in the conductive paste is preferable from about 1 to 4 wt % of the total weight of the conductive paste, and preferably from about 2 to 3 wt % of the conductive paste. For the resin, there is a choice of at least wood rosin and acrylate polymers. For the cellulose, there is a choice of at least ethyl cellulose and propyl cellulose.

Also, in the first step S1, for the additives, there is a choice of at least antioxidants, corrosion inhibitors, antifoaming agents, thickeners, adhesion promoters, coupling agents, static electricity imparting agents, polymerization inhibitors, thixotropic agents and anti-setting agents.

According to an embodiment of the present invention, the adding of additives can give the conductive paste enhanced stability, printability, flatness, reactivity and powder adhesion.

Some examples of the additives are polyethylene glycol ester compounds, polyethylene glycol ether compounds, polyoxyethylene sorbitan ester compounds, sorbitan alkyl ester compounds, aliphatic polycarboxylic acid compounds, poly acid ester amide amine salts, oxidized polyethylene compounds, fatty acid amide-based wax, and castor oil modified derivatives.

Further, additives can also be added in the second step S2. In this case, the types and examples of additives are the same as those used in the first step S1. It should be noted that a total amount of the additives added in the first and second steps S1, S2 is preferably from about 0.2 to 2.0 wt % of the total weight of the conductive paste.

Also, in the second step S2, the content of the lead oxide is preferably from about 0.5 to 3.0 wt %, and most preferably from about 1.0 to 2.0 wt %, of the total weight of the conductive paste.

Also, in the second step S2, a total content of the glass powder and lead oxide is preferably from about 1.0 to 6.0 wt %, and most preferably from about 2.0 to 5.0 wt %, of the total weight of the conductive paste.

For the glass powder, there is a choice of vanadium-based glass powder, bismuth-based glass powder, and glass powder containing other metals. The glass powder used is preferably selected from the types shown in Table 1, and is most preferably selected from the glass powder containing a lead oxide, including but not limited to lead monoxide (PbO). The use of a glass powder containing a lead oxide is more helpful in forming the above-mentioned fire-through path. It is possible to use only one type of glass powder. However, it is also possible to use a combination of different types of glass powders.

TABLE 1

| | |
|---|---|
| Glass | V₂O₅—B₂O₃—Al₂O₃—ZnO—BaO |
| powder 1 | |
| Glass | Bi₂O₃—ZnO—SiO₂—B₂O₃—Al₂O₃ |
| powder 2 | |
| Glass | Bi₂O₃—B₂O₃—SiO₂—Al₂O₃—ZnO—BaO—MgO—Na₂O |
| powder 3 | |
| Glass | PbO—ZnO—B₂O₃— SiO₂—Al₂O₃ |
| powder 4 | |
| Glass | PbO—ZnO—B₂O₃—SiO₂ |
| powder 5 | |
| Glass | PbO—ZnO—B₂O₃ |
| powder 6 | |
| Glass | PbO—ZnO |
| powder 7 | |
| Glass | B₂O₃—ZnO—Al₂O₃—Bi₂O₃—Sb₂O₃—P₂O₅ |
| powder 8 | |

Please refer to Table 2. An embodiment of the conductive paste according to the present invention will be described below.

TABLE 2

| | Content |
|---|---|
| Composition | (wt %) |
| Resin (or cellulose) | 1~4 |
| Organic solvent | 10~25 |
| Additive | 0.2~2.0 |
| Glass powder + Lead oxide | 1~6 |
| Aluminum powder | 60~85 |

In this embodiment, the conductive paste contains from about 1 to 4 wt % resin (or cellulose); from about 10 to 25 wt % organic solvent; from about 0.2 to 2.0 wt % additive; from about 1 to 6 wt % glass powder and lead oxide, including from about 0.5 to 3.0 wt % lead oxide; and from about 60 to 85 wt % aluminum powder.

Further, according to another preferred embodiment of the present invention, the conductive paste further contains from about 5 to 20 wt %, preferably from about 10 to 15 wt %, aluminum-silicon alloy powder. In this case, a total content of the aluminum powder and aluminum-silicon alloy powder is from about 60 to 85 wt % of the total weight of the conductive paste.

It is found by the inventor that the use of aluminum-silicon alloy powder in place of a part of the aluminum powder is more helpful in providing the conductive paste with an enhanced fire-through effect and upgraded electrical characteristics. Table 3 shows the types of aluminum-silicon alloy powders that can be used in the above-mentioned preferred embodiment of the present invention.

TABLE 3

| | |
|---|---|
| Aluminum-silicon alloy | AlSi alloy (Si 12 wt %) D50 = 1~2 μm |
| powder 1 | |
| Aluminum-silicon alloy | AlSi alloy (Si 20 wt %) D50 = 1~2 μm |
| powder 2 | |
| Aluminum-silicon alloy | AlSi alloy (Si 20 wt %) D50 = 6~7 μm |
| powder 3 | |

The fire-through effect and the electrical characteristics of the conductive paste can be further upgraded by using any one of the aluminum-silicon alloy powders 1-3 according to the above preferred embodiment of the present invention, that is, by using an aluminum-silicon alloy powder that contains from about 12 to 20 wt % silicon and has a median particle diameter (D50) from about 1 to 7 μm.

(Preparation of Conductive Paste) Comparative examples 1-9 and Examples 1-14 of the conductive paste according to the present invention are prepared according to the above-described first step Si and second step S2 using different mix proportions, as shown in Table 4.

TABLE 4

| | | Organic | | Glass | Glass | Glass | Organic | |
|---|---|---|---|---|---|---|---|---|
| Example No. | Resin | solvent | Additive | powder 3 | powder 6 | powder 8 | phosphide | PbO |
| Comparative | 1.76% | 16.44% | 1.00% | 2.65% | 0.15% | | | |
| example 1 | | | | | | | | |
| Comparative | 1.79% | 16.06% | 1.00% | 2.65% | 0.50% | | | |
| example 2 | | | | | | | | |
| Comparative | 1.79% | 15.56% | 1.00% | 2.65% | 1.00% | | | |
| example 3 | | | | | | | | |
| Comparative | 1.57% | 14.78% | 1.00% | 2.65% | 2.00% | | | |
| example 4 | | | | | | | | |
| Comparative | 1.36% | 13.99% | 1.00% | 2.65% | 3.00% | | | |
| example 5 | | | | | | | | |
| Comparative | 1.76% | 16.44% | 1.00% | | 0.15% | 2.65% | | |
| example 6 | | | | | | | | |
| Comparative | 1.55% | 15.66% | 1.00% | | 0.15% | 2.65% | 1.00% | |
| example 7 | | | | | | | | |
| Example 1 | 1.52% | 16.18% | 1.00% | 2.65% | 0.15% | | | 0.50% |
| Example 2 | 1.59% | 15.82% | 1.00% | 2.65% | 0.15% | | | 0.80% |
| Example 3 | 1.55% | 15.66% | 1.00% | 2.65% | 0.15% | | | 1.00% |
| Example 4 | 1.55% | 15.16% | 1.00% | 2.65% | 0.15% | | | 1.50% |
| Example 5 | 1.55% | 14.66% | 1.00% | 2.65% | 0.15% | | | 2.00% |
| Example 6 | 1.55% | 14.16% | 1.00% | 2.65% | 0.15% | | | 2.50% |
| Comparative | 1.86% | 18.14% | 1.00% | | | | | 1.00% |
| example 8 | | | | | | | | |
| Compartive | 1.75% | 16.75% | 1.00% | | | | | 2.50% |
| example 9 | | | | | | | | |
| Example 7 | 1.55% | 15.66% | 1.00% | 2.65% | 0.15% | | | |
| Example 8 | 1.55% | 15.66% | 1.00% | 2.65% | 0.15% | | | |
| Example 9 | 1.99% | 15.21% | 1.00% | 2.65% | 0.15% | | | 1.00% |
| Example 10 | 1.89% | 15.31% | 1.00% | 2.65% | 0.15% | | | 1.00% |
| Example 11 | 1.89% | 15.31% | 1.00% | 2.65% | 0.15% | | | 1.00% |
| Example 12 | 1.89% | 15.31% | 1.00% | 2.65% | 0.15% | | | 1.00% |
| Example 13 | 1.89% | 15.31% | 1.00% | 2.65% | 0.15% | | | 1.00% |
| Example 14 | 1.89% | 15.31% | 1.00% | 2.65% | 0.15% | | | 1.00% |

| | | | Al—Si | Al—Si | Al—Si | | |
|---|---|---|---|---|---|---|---|
| | | | alloy | alloy | alloy | Al | |
| Example No. | PbO₂ | Pb₃O₄ | powder 1 | powder 2 | powder 3 | powder | Total |
| Comparative | | | | | | 78.00% | 100.00% |
| example 1 | | | | | | | |
| Comparative | | | | | | 78.00% | 100.00% |
| example 2 | | | | | | | |
| Comparative | | | | | | 78.00% | 100.00% |
| example 3 | | | | | | | |
| Comparative | | | | | | 78.00% | 100.00% |
| example 4 | | | | | | | |
| Comparative | | | | | | 78.00% | 100.00% |
| example 5 | | | | | | | |
| Comparative | | | | | | 78.00% | 100.00% |
| example 6 | | | | | | | |
| Comparative | | | | | | 78.00% | 100.00% |
| example 7 | | | | | | | |
| Example 1 | | | | | | 78.00% | 100.00% |
| Example 2 | | | | | | 78.00% | 100.00% |
| Example 3 | | | | | | 78.00% | 100.00% |
| Example 4 | | | | | | 78.00% | 100.00% |
| Example 5 | | | | | | 78.00% | 100.00% |
| Example 6 | | | | | | 78.00% | 100.00% |
| Comparative | | | | | | 78.00% | 100.00% |
| example 8 | | | | | | | |
| Compartive | | | | | | 78.00% | 100.00% |
| example 9 | | | | | | | |
| Example 7 | 1.00% | | | | | 78.00% | 100.00% |
| Example 8 | | 1.00% | | | | 78.00% | 100.00% |
| Example 9 | | | 5.00% | | | 73.00% | 100.00% |
| Example 10 | | | 10.00% | | | 68.00% | 100.00% |
| Example 11 | | | 15.00% | | | 63.00% | 100.00% |
| Example 12 | | | 20.00% | | | 58.00% | 100.00% |
| Example 13 | | | | 10.00% | | 68.00% | 100.00% |
| Example 14 | | | | | 10.00% | 68.00% | 100.00% |

More specifically, Comparative example 1 is prepared in the following manner. In the first step S1, the organic carrier is prepared by dissolving 1.79 parts of ethyl cellulose in 16.46 parts of diethylene glycol monobutyl ether, which is used as the organic solvent.

A first glass material composed of Bi₂O₃—B₂O₃—SiO₂—Al₂O₃—ZnO—BaO—MgO—Na₂O (i.e. glass powder 3) and a second glass material composed of PbO—ZnO—B₂O₃ (i.e. glass powder 6) are prepared.

In the second step S2, use a mixer or a three-roller mill to dissolve 2.65 parts of the first glass material, 0.1 part of the second glass material, 78.0 parts of aluminum powder, 1.0 part of thixotropic agent, and 18.25 parts of ethyl cellulose in the organic carrier prepared in the first step S1, and to mix, mill and disperse the resulting solution to prepare the conductive paste.

Comparative examples 2-6 are prepared using the mix proportions shown in Table 4 and in the same manner as Comparative example 1.

Comparative example 7 is prepared using the mix proportion shown in Table 4 and in the same manner as Comparative example 1. In Comparative example 7, the organophosphide used is Di(2-ethylhexyl)phosphoric acid, which is added along with the aluminum powder and the glass powder in the second step S2.

Comparative examples 8-9 are prepared using the mix proportions shown in Table 4 and in the same manner as Comparative example 1. In Comparative examples 8-9, PbO (lead monoxide) is added along with aluminum powder in the second step S2. It should be noted Comparative examples 8-9 do not contain any glass powder. Therefore, no glass powder is added in the second step S2 of preparing Comparative examples 8-9.

Further, Examples 1-8 are prepared using the mix proportions shown in Table 4 and in the same manner as Comparative example 1. Herein, the lead oxide (PbO, PbO₂, or Pb₃O₄) used in Examples 1-8 is added along with aluminum powder and glass powders in the second step S2.

Further, Examples 9-14 are prepared using the mix proportions shown in Table 4 and in the same manner as Comparative example 1. Herein, the lead oxide (which is PbO) used in Examples 9-14 is added along with aluminum powder and glass powders in the second step S2; and the aluminum-silicon alloy powder 1, 2 or 3 is also added along with aluminum powder and glass powders in the second step S2.

### TESTING EXAMPLE

A solar cell includes, for example, a p-type silicon semiconductor substrate having a thickness from 150 to 250 μm. An n-type impurity layer having a thickness from about 0.3 to 0.6 μm is formed on a light-receiving side of the p-type silicon semiconductor substrate; and an antireflection layer formed of a silicon nitride film, which is also referred to as a front side passivation layer, as well as a gate electrode are formed on the n-type impurity layer. Further, on a back side of the p-type silicon semiconductor substrate that faces away from the light-receiving side, there is an antireflection layer formed of a silicon nitride film, which is also referred to as a back side passivation layer. The back side passivation layer is structured by first depositing Al₂O₃ or SiO₂ or TiO₂ on a silicon wafer, and then depositing Si₃N₄ on the deposited Al₂O₃ or SiO₂ or TiO₂.

The conductive pastes of Comparative examples 1-9 and Examples 1-14 are separately printed on the back side of the above-mentioned solar cell or PERC silicon solar cell using a printing machine. The same screen printing plate (having a linewidth of 130 μm and an emulsion thickness of 20 μm) and the same printing conditions are used. Wherein, the back side of the solar cell has already been printed with a back side silver paste and does not include any laser contact opening (LCO). The conducting electrode so formed has a thickness from about 15 to 30 μm. After the printed conductive paste is dried, the front side of the solar cell is further printed with a front side silver paste. The solar cell is then dried at 150 to 250° C. before it is sent into a high-temperature sintering furnace for an organic burn-off process and aluminum layer sintering process. In the Testing example, a continuous track is used to convey the solar cell for the purpose of speeding up the sintering process. The track speed is from 180 to 320 inches/minute and the sintering process is performed at a sintering temperature from 720 to 820° C. In the course of sintering, the glass powder(s) and the lead oxide react with the passivation layer to destroy or fire through the back side passivation layer, so as to manufacture the solar cell.

A solar cell electrical measurement and a warpage test are conducted for the solar cells manufactured using the conductive pastes of Examples 1-14 and of Comparative examples 1-9 in the following described manner, and the results are shown in Table 5.

<Solar cell electrical measurement>A solar cell simulation test system is used to test the photovoltaic conversion efficiency (Eff (%)), the open-circuit voltage (V_{oc} (V)), the short-circuit current (I_{sc} (A)), and the fill factor (FF (%)) of the solar cells. The simulation test machine used is QuickSun Cell Solar Simulator Model 120CA available from Endeas Qy, Finland.

<Warpage>

After the sintering process, the solar cells are cooled for one hour and a laser rangefinder is used to measure the thickness of the solar cells. Solar cells that have a thickness over 1.5 mm are considered not good.

TABLE 5

| Example No. | Eff (%) | Voc (V) | Isc (A) | FF (%) | Warpage (mm) |
|---|---|---|---|---|---|
| Comparative | 4.42% | 1.0869% | 3.722% | 26.84 | 0.73 |
| example 1 | | | | | |
| Comparative | 4.78% | 1.0823% | 4.071% | 26.70 | 0.76 |
| example 2 | | | | | |
| Comparative | 4.91% | 1.0961% | 4.116% | 26.78 | 0.74 |
| example 3 | | | | | |
| Comparative | 5.85% | 1.0229% | 5.050% | 27.84 | 0.77 |
| example 4 | | | | | |
| Comparative | 5.95% | 1.0306% | 5.067% | 28.01 | 0.97 |
| example 5 | | | | | |
| Comparative | 8.53% | 0.9699% | 7.060% | 30.63 | 0.68 |
| example 6 | | | | | |
| Comparative | 15.55% | 0.6549% | 9.566% | 67.50 | 0.69 |
| example 7 | | | | | |
| Example 1 | 18.09% | 0.6516% | 9.122% | 74.84 | 0.61 |
| Example 2 | 18.51% | 0.6536% | 9.175% | 75.92 | 0.61 |
| Example 3 | 18.99% | 0.6458% | 9.187% | 78.70 | 0.62 |
| Example 4 | 18.92% | 0.6359% | 9.168% | 79.80 | 0.63 |
| Example 5 | 18.79% | 0.6304% | 9.124% | 80.34 | 0.62 |
| Example 6 | 18.55% | 0.6484% | 9.130% | 77.05 | 1.28 |
| Comparative | 8.50% | 0.9223% | 5.513% | 41.09 | 0.76 |
| example 8 | | | | | |
| Comparative | 10.89% | 0.8223% | 7.220% | 45.09 | 0.96 |
| example 9 | | | | | |
| Example 7 | 15.55% | 0.6715% | 8.920% | 62.91 | 0.62 |
| Example 8 | 15.50% | 0.6715% | 8.916% | 62.71 | 0.62 |
| Example 9 | 19.86% | 0.6583% | 9.536% | 77.79 | 0.79 |
| Example 10 | 20.10% | 0.6527% | 9.551% | 79.297 | 0.85 |
| Example 11 | 20.48% | 0.6497% | 9.709% | 79.853 | 0.93 |
| Example 12 | 19.82% | 0.6479% | 9.523% | 78.98 | 0.85 |
| Example 13 | 20.26% | 0.6558% | 9.513% | 79.871 | 0.63 |
| Example 14 | 20.20% | 0.6569% | 9.532% | 79.297 | 0.62 |

From the results in Table 5, it can be found that, with the gradually increased content of the glass powder 6 in Comparative examples 1-5 (increased from 0.15% in Comparative example 1 to 3.00% in Comparative example 5) and the increased lead-containing oxide in the glass powder, the photovoltaic conversion efficiencies of the solar cells using Comparative examples 1-5, after the sintering process, are sequentially increased from 4.24% in the case of using Comparative example 1 to 5.95% in the case of using Comparative example 5, while the fill factors thereof are also sequentially increased. However, due to insufficient fire-through effect, these solar cells all are in a high V_{oc} state exceeded 1.0V. Therefore, it is found the use of glass powder containing lead-containing oxide can indeed achieve some extent of the fire-through effect but the effect is not good enough. In other words, a sufficient fire-through effect could not be achieved simply by increasing the content of the lead-containing oxide in the glass powder.

Then, by referring to the solar cells using Comparative example 1 and Example 1, it can be found that, when using a conductive paste that uses a glass powder (preferably a glass powder containing a lead-containing oxide) and a lead oxide (e.g. PbO) in combination, such as Example 1, the photovoltaic conversion efficiency of the solar cell can be largely increased, for example, from 4.24% in the case of using Comparative example 1 to 18.09% in the case of using Example 1, the fill factor is also increased, for example, from 26.84 in the case of using Comparative example 1 to 74.84 in the case of using Example 1, and the V_{oc} is reduced from 1.0869V in the case of using Comparative example 1 to 0.6516V in the case of using Example 1.

Then, from the solar cells using Comparative examples 8-9, it can be found that, when using a conductive paste that has an increased content of lead oxide (i.e. PbO), such as Comparative example 9, the photovoltaic conversion efficiency of the solar cell can also be upgraded, for example, from 8.50% in the case of using Comparative example 8 to 10.89% in the case of using Comparative example 9. However, the photovoltaic conversion efficiency of 10.89% is still not high enough. Further, by referring to the solar cells using Example 1 and Comparative examples 8-9, it can be found that, when using a conductive paste that uses a lead oxide (e.g. PbO) and a glass powder (preferably a glass powder containing a lead-containing oxide) in combination, such as Example 1, the photovoltaic conversion efficiency and the fill factor of the solar cell all are largely increased. For example, the photovoltaic conversion efficiency of 18.09 and the fill factor of 74.84 in the case of using Example 1 all are higher than those in the case of using Comparative examples 8-9.

Therefore, it is found a conductive paste that uses only a lead oxide (e.g. PbO) without using any glass powder, such as Comparative examples 8-9, could not form any fire-through path and accordingly, provides a relatively poor passivation layer firing-through effect. Thus, Comparative examples 8-9 are not suitable for use in the present invention.

Further, by referring to the solar cells using Examples 1-6, it is found that, when using Example 3 that contains 1.00% lead oxide (e.g. PbO), the solar cell can have the best photovoltaic conversion efficiency (18.99%) than any other solar cell that uses Examples 1, 2, 4, 5 or 6. The solar cell using Example 5, which contains 2.00% lead oxide, has a photovoltaic conversion efficiency of 18.79%, which is already slightly lower than that of the solar cell using Example 3.

Therefore, it is found the conductive paste containing from about 0.5 to 3.0 wt % lead oxide can realize the desired effects of the present invention. And, the conductive paste containing from about 1.0 to 2.0 wt % lead oxide can even better realize the desired effects of the present invention.

Then, please refer to the solar cells using Comparative examples 1 and 6. In Comparative example 6, the content of glass powder 6 is the same as that in Comparative example 1 and glass powder 8 that contains a phosphorus compound is used in place of the glass powder 3 used in Comparative example 1. It can be found the solar cell using Comparative example 6 has increased photovoltaic conversion efficiency than the solar cell using Comparative example 1 (i.e. the photovoltaic conversion efficiency is increased from 4.24% in the case of using Comparative example 1 to 8.53% in the case of using Comparative example 6. Also, please refer to Comparative examples 6 and 7, both of which use the phosphorus compound-containing glass powder 8 but Comparative example 7 further uses an organic phosphide, e.g. Di(2-ethylhexyl) phosphoric acid. And, it is found the solar cell using Comparative example 7 provides an increased photovoltaic conversion efficiency of 15.55% while the solar cell using Comparative example 6 has a lower photovoltaic conversion efficiency of 8.53%.

However, compared to the photovoltaic conversion efficiency (18.09%) of the solar cell using Example 1, the photovoltaic conversion efficiency (8.53%) of the solar cell using Comparative example 6 and the photovoltaic conversion efficiency (15.55%) of the solar cell using Comparative example 7 are still insufficient. Therefore, Example 1 that uses glass powders and a lead oxide in combination is better than Comparative example 6, which uses a phosphorus compound-containing glass powder, and Comparative example 7, which uses a phosphorus compound-containing glass powder and an organic phosphide in combination.

In addition, it is also found by the inventor that, while the use of a phosphorus compound-containing glass powder and an organic phosphide in combination as in Comparative example 7 can also considerably increase the fire-through effect of the conductive paste, the organic phosphide is hydrophilic, high polar and nonflammable, and accordingly, tends to absorb moisture and becomes aggregated and caked, rendering the conductive paste unstable. Therefore, Comparative example 7 is also not suitable for use in the present invention.

Further, by referring to Comparative example 1 and Examples 7-8, it is found a conductive paste using glass powders and a lead oxide (such as PbO₂ or Pb₃O₄) in combination, such as in Examples 7-8, can also provide the effect of increasing the photovoltaic conversion efficiency. According to Table 5, the solar cell using Comparative example 1 has a lower photovoltaic conversion efficiency of 4.42%, while the solar cells using Examples 7-8 have increased photovoltaic conversion efficiencies of 15.55% and 15.50%, respectively. Therefore, the use of a lead oxide-containing glass powder and a lead oxide in combination in the conductive paste can achieve the desired effect of the present invention.

Moreover, by referring to Example 3 and Examples 9-14, it is found by the inventor that, based on the condition of having a fixed content of PbO in the conductive paste, the use of an aluminum-silicon alloy power in place of a part of the aluminum powder, such as in Examples 9-14, enables the solar cells using such conductive pastes to provide an even better photovoltaic effect. For example, the photovoltaic conversion efficiency is increased from 18.99% in the case of using Example 3 to more than 19.82% in the case of using Examples 9-14, which use aluminum powder and an aluminum-silicon alloy powder at the same time. Therefore, by using a specific percentage of an aluminum-silicon alloy powder in the conductive paste, for example, using from about 5 to 20 wt % aluminum-silicon alloy powder in place of a part of the aluminum powder, it is able to further realize the desired effect of the present invention.

Moreover, by comparing Example 11 with Example 12, it is found, when the content of the aluminum-silicon alloy powder is increased from 15% in Example 11 to 20% in Example 12, the photovoltaic conversion efficiency (20.48%) of the solar cell using Example 11 is reduced to 19.82% in the solar cell using Example 12. Therefore, it is preferable the conductive paste contains from about 10 to 15 wt % aluminum-silicon alloy powder. Further, it is more preferable to use an aluminum-silicon alloy powder that contains from about 12 to 20 wt % silicon and has a median particle diameter (D50) of from about 1 to 7 μm, such as any one of the aluminum-silicon alloy powders 1-3 shown in Table 3.

Further, please compare the solar cells using Examples 10, 13 and 14 with one another. It can be found the photovoltaic conversion efficiency is increased when the silicon content in the aluminum-silicon alloy powder used is increased. For example, the photovoltaic conversion efficiency is 20.10% when using Example 10 that includes an aluminum-silicon alloy powder 1 having a content of 12 wt % silicon; and the photovoltaic conversion efficiency is further increased to 20.26% and 20.20% when using Examples 13 and 14 that include aluminum-silicon alloy powder 2 and 3 having a content of 20 wt % silicon, respectively.

The solar cell using Example 11 is the best embodiment according to the present invention because it has the highest photovoltaic conversion efficiency of 20.48% compared to other solar cells. Wherein, Example 11 contains total 3.80 wt % glass powders and lead oxide while the content of lead oxide (i.e. PbO) is 1.00 wt % of the conductive paste and the content of aluminum-silicon alloy powder is 15 wt % of the conductive paste. From the above analyses, it is found, for the conductive paste of the present invention, the most ideal mix proportion is total 2.0 to 5.0 wt % lead oxide-containing glass powders and a lead oxide; 1.0 to 2.0 wt % lead oxide; 10 to 15 wt % aluminum-silicon alloy powder; and total 60 to 85 wt % aluminum powder and an aluminum-silicon alloy powder.

In conclusion, when the conductive paste of the present invention contains specific percentages of glass powders and lead oxide is used, the solar cells so manufactured can have increased photovoltaic conversion efficiency without the need of using any expensive laser drilling apparatus, large plant space and any precision-alignment printing machine. With these advantages, the conductive paste of the present invention is able to promote photovoltaic industry upgrading.

Moreover, the photovoltaic conversion efficiency of the solar cell can be further increased by using the conductive paste of the present invention that contains specific percentages of glass powders, lead oxide and aluminum-silicon alloy powder.

The present invention has been described with some preferred embodiments thereof and it is understood that the preferred embodiments are only illustrative and not intended to limit the present invention in any way and many changes and modifications in the described embodiments can be carried out without departing from the scope and the spirit of the invention that is intended to be limited only by the appended claims.

What is claimed is:

1. A conductive paste, comprising:
an aluminum powder;
an organic carrier composed of an organic solvent and resin or cellulose;
a glass powder; and
a lead oxide; and
wherein a total content of the glass powder and the lead oxide is from about 1.0 to 6.0 wt % of the conductive paste; and a content of the lead oxide is from about 0.5 to 3.0 wt % of the conductive paste.

2. The conductive paste as claimed in claim 1, wherein the total content of the glass powder and the lead oxide is from about 2.0 to 5.0 wt % of the conductive paste, and the content of the lead oxide is from about 1.0 to 2.0 wt % of the conductive paste.

3. The conductive paste as claimed in claim 1, wherein the glass powder is a glass powder containing a lead-containing oxide.

4. The conductive paste as claimed in claim 1, wherein the lead oxide is lead monoxide (PbO).

5. The conductive paste as claimed in claim 1, wherein the organic solvent is selected from the group consisting of terpineol, 2,2,4-trimethyl-1,3-pentanediol monoisobutyrate (texanol), diethylene glycol monobutyl ether, and any combination thereof; and wherein a content of the organic solvent is from about 10 to 25 wt % of the conductive paste.

6. The conductive paste as claimed in claim 1, wherein the organic carrier further includes additives selected from the group consisting of antioxidants, corrosion inhibitors, antifoaming agents, thickeners, adhesion promoters, coupling agents, static electricity imparting agents, polymerization inhibitors, thixotropic agents, ant-setting agents, and any combination thereof;
and a total content of the additives being from about 0.2 to 2.0 wt % of the conductive paste.

7. The conductive paste as claimed in claim 1, further comprising an aluminum-silicon alloy powder; a content of the aluminum-silicon alloy powder being from about 5 to 20 wt % of the conductive paste; and a total content of the aluminum powder and the aluminum-silicon alloy powder being from about 60 to 85 wt % of the conductive paste.

8. The conductive paste as claimed in claim 2, further comprising an aluminum-silicon alloy powder; a content of the aluminum-silicon alloy powder being from about 5 to 20 wt % of the conductive paste; and a total content of the aluminum powder and the aluminum-silicon alloy powder being from about 60 to 85 wt % of the conductive paste.

9. The conductive paste as claimed in claim 7, wherein the content of the aluminum-silicon alloy powder is from about 10 to 15 wt % of the conductive paste.

10. The conductive paste as claimed in claim 7, wherein the aluminum-silicon alloy powder contains from about 12 to 20 wt % silicon and has a median particle diameter (D50) from about 1 to 7 μm.

11. A solar cell having a back side passivation layer, being characterized in comprising the conductive paste as claimed in claim 1.

12. A solar cell having a back side passivation layer, being characterized in comprising the conductive paste as claimed in claim 2.

13. A solar cell having a back side passivation layer, being characterized in comprising the conductive paste as claimed in claim 3.

14. A solar cell having a back side passivation layer, being characterized in comprising the conductive paste as claimed in claim 4.

15. A solar cell having a back side passivation layer, being characterized in comprising the conductive paste as claimed in claim 5.

16. A solar cell having a back side passivation layer, being characterized in comprising the conductive paste as claimed in claim 6.

17. A solar cell having a back side passivation layer, being characterized in comprising the conductive paste as claimed in claim 7.

18. A solar cell having a back side passivation layer, being characterized in comprising the conductive paste as claimed in claim 8.

19. A solar cell having a back side passivation layer, being characterized in comprising the conductive paste as claimed in claim 9.

20. A solar cell having a back side passivation layer, being characterized in comprising the conductive paste as claimed in claim 10.
